(19) United States
(12) Patent Application Publication
(10) Pub. No.: US 2004/0046684 A1
(43) Pub. Date: Mar. 11, 2004

(54) Low power pipeline analog-to-digital converter

(76) Inventor: Paolo Cusinato, Villeneuve Loubet (FR)

Correspondence Address: TEXAS INSTRUMENTS INCORPORATED, P O BOX 655474, M/S 3999, DALLAS, TX, 75265

(21) Appl. No.: 10/241,175

(22) Filed: Sep. 11, 2002

(51) Int. Cl. H03M 1/12

(52) U.S. Cl. 341/161

(57) ABSTRACT

A pipeline analog-to-digital converter (40) includes a plurality of sequentially connected converter stages (42), with each stage having a sample-and-hold circuit (22) for sampling and holding an analog voltage input, an analog-to-digital converter (24) for converting the analog voltage input into an intermediate digital representation, a digital-to-analog converter (26) for converting the digital representation into an intermediate voltage signal and an operational amplifier (46) for amplifying a voltage difference between the output of the sample-and-hold circuit and the intermediate voltage output. A variable bias current is applied to the operational amplifier (46) to conserve power, such that a low current is supplied during sampling and a high current is supplied during amplification.

### CROSS-REFERENCE TO RELATED APPLICATIONS

Not Applicable

### STATEMENT OF FEDERALLY SPONSORED RESEARCH OR DEVELOPMENT

Not Applicable

### BACKGROUND OF THE INVENTION

1. Technical Field

This invention relates in general to mobile electronic devices and, more particularly, to a mobile electronic device using low power analog-to-digital converters.

2. Description of the Related Art

Mobile electronic devices, such as mobile telephones, personal digital assistants (PDAs), smart phones, and other devices require a battery for a power supply. Because it is generally desirable to manufacture a mobile electronic device in a small physical package, the size of the battery must necessarily be small as well.

Many mobile devices, particularly those with communications capabilities, use analog-to-digital converters to translate an analog signal into a digital representation. Analog-to-digital converters can consume considerable amount of power, which significantly reduces battery life.

Therefore, a need has arisen for a low-power analog-to-digital converter.

### BRIEF SUMMARY OF THE INVENTION

In the present invention, a pipeline analog-to-digital converter includes a plurality of sequentially connected converter stages, with each stage having a sample-and-hold circuit for sampling and holding an analog voltage input, an analog-to-digital converter for converting the analog voltage input into an intermediate digital representation, a digital-to-analog converter for converting the digital representation into an intermediate voltage signal and an operational amplifier for amplifying a voltage difference between the output of the sample-and-hold circuit and the intermediate voltage output. A variable bias current is applied to the operational amplifier to conserve power.

The present invention significantly reduces power consumption relative to previously developed pipeline analog-to-digital converters, and is particularly suited to mobile communications devices.

### BRIEF DESCRIPTION OF THE SEVERAL VIEWS OF THE DRAWINGS

For a more complete understanding of the present invention, and the advantages thereof, reference is now made to the following descriptions taken in conjunction with the accompanying drawings, in which:

FIG. 1 illustrates a block diagram of a prior art pipeline analog-to-digital converter (ADC);

FIG. 2 illustrates a block diagram of a stage used in FIG. 1;

FIG. 3 illustrates a block diagram of a pipeline ADC with significantly reduced power consumption;

FIG. 4 illustrates a block diagram of a stage used in FIG. 3;

FIG. 5 illustrates the timing signals Φ_{S} and Φ_{I} and bias current (I_{bias}); and

FIG. 6 illustrates a block diagram of a mobile communications device using the ADC of FIGS. 3 through 5.

### DETAILED DESCRIPTION OF THE INVENTION

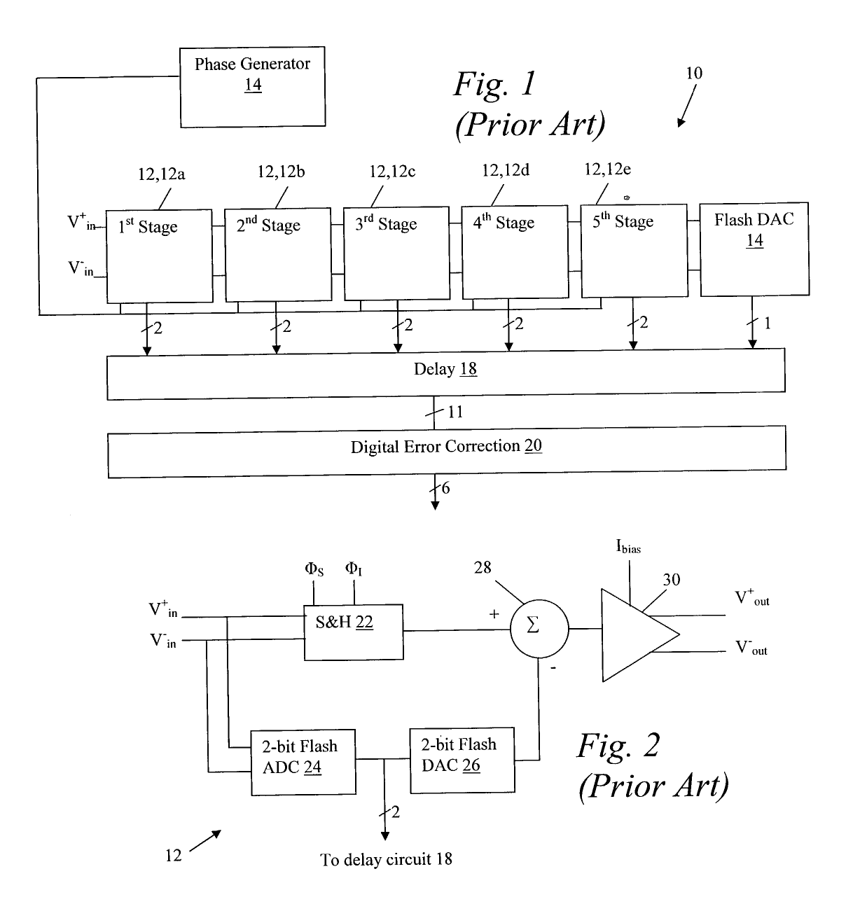

The present invention is best understood in relation to FIGS. 1-6 of the drawings, like numerals being used for like elements of the various drawings.

FIG. 1 illustrates a block diagram of a prior art pipeline analog-to-digital converter (ADC), which outputs a 6-bit word responsive to a differential analog voltage input. The analog-to-digital converter 10 includes a plurality of serially-connected stages 12 (shown individually as stages 12a-e), each stage 12 coupled to a phase generator 16. The first stage 12a receives an analog voltage signal (in the illustrated embodiment, a differential voltage signal) for conversion to a digital signal. The last stage outputs a voltage signal to a flash digital-to-analog converter 14. In the illustrated embodiment for of FIG. 1, each of the five stages 12 output two bits to a delay circuit 18. The output of the delay circuit is received by a digital error correction circuit 20 which outputs a 6-bit result.

The number of stages, number of output bits for each stage, and the number of bits output from the ADC 10 are for illustrative purposes only and could be varied as desired for a particular design.

FIG. 2 illustrates a block diagram of a stage 12 as used in FIG. 1. Each stage receives a voltage at its input, either the input voltage signal to be converted, or an amplified “residue” voltage from the previous stage in the series. In the illustrated embodiment, the input voltage signal is a differential voltage defined by V⁺ᵢₙ and V⁻ᵢₙ. The input voltage is coupled to a sample and hold circuit 22 and to a 2-bit flash analog-to-digital converter 24. The output of the 2-bit flash ADC is coupled to the delay circuit 18 and to a 2-bit flash DAC (digital-to-analog) circuit 26. The output of the flash digital-to-analog circuit 26 is subtracted from the output of the sample and hold circuit 22 in summation block 28. The output of the summation block is amplified by operational amplifier 30 to generate V⁺ₒᵤₜ and V⁻ₒᵤₜ. Operational amplifier 30 is biased by current I_{bias}.

In operation, during a sampling phase, the input voltage at each stage is sampled and held steady by the sample and hold circuit 22. During this time, the operational amplifier in each pipeline stage is auto-zeroed by connecting the operational amplifier in unity gain mode. Flash ADC 24 converts the differential input voltage into a coarse digital representation and presents the bits to the delay circuit 18. The digital representation is converted back into an analog voltage by flash DAC 26. Summation circuit 28 generates a residue voltage that is the difference between the input voltage and the voltage output from flash DAC 26. In other words, the voltage output from summation circuit 28 is the amount of voltage not accounted for by the digital output of flash ADC 24. During an integration phase, the voltage output from summation circuit 28 is amplified by operational amplifier 30 to produce an amplified residue differential output voltage that is passed to the next stage 12. Once a stage 12 is finished processing a sample, it can start processing the next sample.

The delay circuitry time aligns the outputs from the various stages 12 and the output DAC 14. Since, in the illustrated embodiment, the input voltage signal must pass sequentially through five stages and the flash DAC, the delay circuit 18 is needed to store partial results as the signal passes through the pipeline ADC 10. When the output bits from all stages are ready, the delay circuit 18 outputs the bits to the digital error correction circuit 20 to increase the accuracy of the pipeline ADC 10.

A problem with the ADC 10 of FIG. 1 is the amount of power consumed by the stages, and particularly with the operational amplifiers 30 of each stage. Because there are a plurality of stages 12 for each ADC 10, and because there may be multiple ADCs 10 per device, the power consumption may be significant.

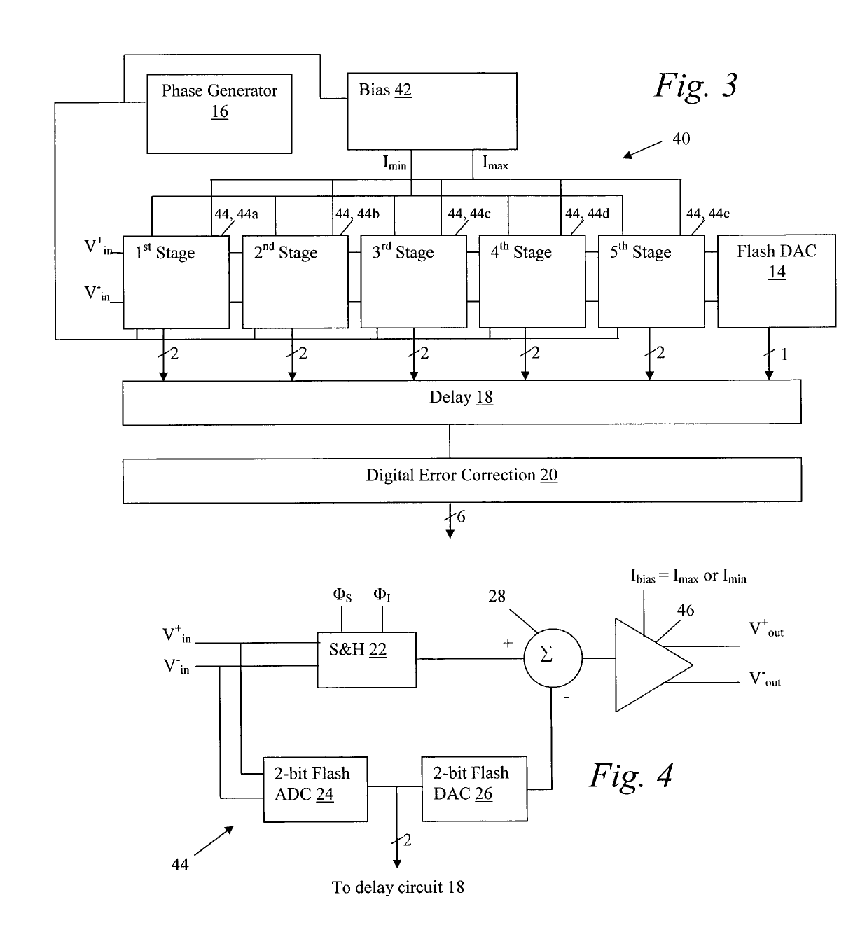

FIG. 3 illustrates a block diagram of a pipeline ADC 40 with significantly reduced power consumption. The pipeline ADC 40 can use the same delay circuit 18, digital error correction circuit 20 and flash DAC 14 as described in connection with FIG. 1. However, a bias current circuit 42 controls the bias current to the operational amplifier of stages 44 (individually referenced as stages 44a-e) to reduce power consumption. The bias current circuit generates two current sources, Iₘᵢₙ and Iₘₐₓ, for each stage; depending upon a current phase, one of the two current sources will be enabled.

FIG. 4 illustrates a block diagram of a stage 44. The stage can be of the same design as shown in FIG. 2, with the exception that the operational amplifier 46 receives a variable current from bias current circuit 42.

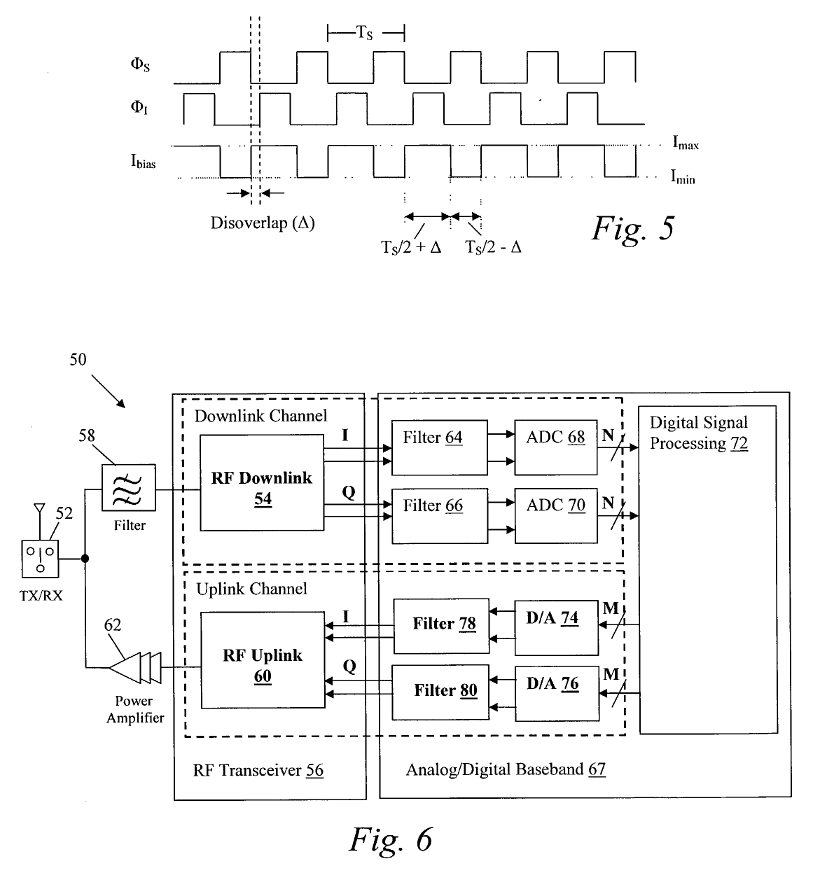

The operation of the pipeline ADC 40 of FIGS. 3 and 4 is described in conjunction with the timing diagram of FIG. 5. FIG. 5 illustrates the timing signals Φ_{S} and Φ_{I} (from phase generator 16) that control the bias current (I_{bias}) to each stage 42.

The core of the stages 42 is the operational amplifier 46. The overall performance of the ADC 40 is strongly dependent upon the operational amplifiers 46. In the illustrated case, the operational amplifiers 46 must settle with 6-bit resolution within Ts/2 (i.e., one-half of a Φ_{S} clock cycle) with a specified DC gain. The operational amplifiers can be the most power consuming component of the ADC 40.

However, the circuit of FIGS. 3 through 5 varies the bias current to the operational amplifier 46 between Iₘₐₓ and Iₘᵢₙ during the operation of the circuit, as shown in FIG. 5. The performance criteria of the operational amplifiers 46 need only be met during the integration (amplification) phase Φ_{I} high) as the operational amplifiers 46 are amplifying the residue for the following stage. When the operational amplifiers 46 are auto-zeroed during the sampling phase Φ_{S} high) their performance can be reduced with a negligible impact on the overall performance of the ADC 40.

In order to reduce the overall power consumption, the bias current circuit 42 varies the bias current to operational amplifiers 46 of the ADC 40 during the sampling and the auto-zero phases. During the integration phase (Φ_{I} high), the operational amplifiers 46 receive Iₘₐₓ. During the sampling phase (Φ_{S} high), the operational amplifiers 46 receive the reduced biasing current Iₘᵢₙ thus reducing the power consumption of the operational amplifiers 46 during the sampling period.

As shown in FIG. 5, I_{bias} is switched on the raising and falling edges of Φ_{S} (clock phase which manages the sampling phase) in order to have a stable Iₘₐₓ during the auto-zero phase (Φ_{I} high), thus maintaining the linearity of the ADC 40. Particular care should be used in the design of the phase generator 16. In order to ensure a stable Iₘₐₓ during the integration phase, the disoverlap generated by the phase generator 16 should be greater than the settling time of the bias current circuit 42.

The bias circuitry can be designed to provide an optional standard static bias current, if desired in certain situations.

Using test data, during the integration phase, each operational amplifier 46 received 1.1 mA (I_{MAX}), while during the sampling phase (when the operational amplifiers were auto-zeroed), each operational amplifier received 600 uA (I_{MIN}). Thus, the average current consumption per period was 850 uA (ignoring the disoverlap, Δ, which is negligible compared to T_{S}) with a power consumption saving close to 20% compared to using a standard static bias current.

Table 1 illustrates the measured performance of an ADC 40 using switched biasing current (SWB) and static biasing current (STB).

TABLE 1
PERFORMANCE COMPARISON

| Resolution | 6 bit | |
|---|---|---|
| Conversion rate (Fₛ) | 15.36 MHz | |
| Input signal bandwidth | 1.92 MHz | |
| Differential input range | 2.05 Vₚₚ | |
| Mode | SWB | STB |
| SNDR | | |
| (f_{IN} = 100 kHz) | 38.2 dB | 38.6 dB |
| (f_{IN} = 1 MHZ) | 38.1 dB | 38.4 dB |
| SNR | | |
| (f_{IN} = 100 kHz) | 39.3 dB | 39.8 dB |
| (f_{IN} = 1 MHz) | 39.2 dB | 39.7 dB |
| ENOB | | |
| (f_{IN} = 100 kHz) | 6.27 | 6.33 |
| (f_{IN} = 1 MHz) | 6.25 | 6.31 |
| (Effective Number Of Bits) | | |
| SFDR | | |
| (f_{IN} = 100 kHz) | 40 dB | 42 dB |
| (f_{IN} = 1 MHz) | 41 dB | 43 dB |
| Power consumption | 16 mW | 20 mW |

| | |
|---|---|
| Supply voltage | 2.8 V |
| Active area | 0.6 × 2.3 mm² |
| Technology | 3370a12 |

Using a standard biasing at constant current (input signals at −1 dB with fᵢₙ=1 MHz and Fs=15.36 MHz), the Signal-to-Noise-and-Distortion-Ratio (SNDR) was found to be 32.6 dB (noise integrated up to Fs/2) or 38.4 dB if considering the oversampling factor (noise integrated up to 1.92 MHz). The Signal-to-Noise Ratio (SNR) was found to be 33.7 dB (noise integrated up to Fs/2) or 39.7 dB if considering the oversampling factor (noise integrated up to 1.92 MHz). The Spurious-Free-Dynamic-Range (SFDR) is limited by third order distortion for all input frequencies and was found to be 43 dB.

Working with the adaptive biasing scheme, the SNDR was found to be 32 dB (noise integrated up to Fs/2) or 38.1 dB factor (noise integrated up to 1.92 MHz). The SNR was found to be 33.4 dB (noise integrated up to Fs/2) or 39.2 dB if considering the oversampling factor. Also in these conditions the SFDR is limited by third order distortion for all input frequencies and was found to be 41 dB.

Hence, the reduction in power consumption provided by the variation of the bias current has very little effect on the performance criteria of the ADC 40.

While the ADC 40 has been described in connection with a particular implementation, the invention may be used with any pipeline analog-to-digital converter to reduce power consumption without significant reduction in performance. Hence, the quantization and number of stages could be varied as desired for a particular pipeline ADC design. Further, the voltage signal input to each stage can be either differential or non-differential.

FIG. 6 illustrates the use of pipeline ADCs 40 in a communications circuit 50. An antenna 52 receives and transmits analog signals. An RF (radio frequency) downlink 54 of an RF transceiver 56 is coupled to antenna 52 via filter 58. An RF Uplink 60 of RF transceiver 56 is coupled to antenna 52 via power amplifier 62. The RF downlink 54 outputs I and Q data to filters 64 and 66, respectively, of analog/digital baseband circuit 67. The outputs of filters 64 and 66 are received by pipeline ADCs 68 and 70, respectively, to convert the I and Q signals into digital form to be processed by digital signal processing circuit 72. Digital data from digital signal processing circuit 72 to DACs 74 and 76, where it is converted into analog signals. The analog signals are filtered by filters 78 and 80, and passed to RF Uplink 60.

The pipeline ADC describe in connection with FIGS. 3 through 5 can be used to implement ADCs 68 and 70 in the circuit of FIG. 6 in order to reduce power consumption. The communications circuit can be used in a number of devices to provide wireless communication.

Although the Detailed Description of the invention has been directed to certain exemplary embodiments, various modifications of these embodiments, as well as alternative embodiments, will be suggested to those skilled in the art. The invention encompasses any modifications or alternative embodiments that fall within the scope of the claims.

1. A pipeline analog-to-digital converter comprising:
a plurality of sequentially connected converter stages, each stage comprising:
a sample-and-hold circuit for sampling and holding an analog voltage input;
an analog-to-digital converter for converting the analog voltage input into an intermediate digital representation;
a digital-to-analog converter for converting the digital representation into an intermediate voltage signal;
an operational amplifier for amplifying a voltage difference between the output of the sample-and-hold circuit and the intermediate voltage output, wherein a variable bias current is applied to the operational amplifier to conserve power.

2. The pipeline analog-to-digital converter of claim 1 and further comprising a bias current control circuit to generate variable current signals to the operational amplifiers to each stage.

3. The pipeline analog-to-digital converter of claim 2 and further comprising a phase generator to control said bias current control circuit.

4. The pipeline analog-to-digital converter of claim 1 and wherein a first current is applied to the operational amplifiers during a first phase where the operational amplifiers are amplifying the voltage difference and wherein a second current of smaller magnitude is applied to the operational amplifiers during a second phase where the output of the operational amplifiers is reset to a predetermined value.

5. A mobile electronic device comprising:
digital processing circuitry;
one or more analog-to-digital converters comprising a plurality of sequentially connected converter stages, each stage comprising:
a sample-and-hold circuit for sampling and holding an analog voltage input;
an analog-to-digital converter for converting the analog voltage input into an intermediate digital representation;
a digital-to-analog converter for converting the digital representation into an intermediate voltage signal;
an operational amplifier for amplifying a voltage difference between the output of the sample-and-hold circuit and the intermediate voltage output, wherein a variable bias current is applied to the operational amplifier to conserve power.

6. The pipeline analog-to-digital converter of claim 5 and further comprising a bias current control circuit to generate variable current signals to the operational amplifiers to each stage.

7. The pipeline analog-to-digital converter of claim 6 and further comprising a phase generator to control said bias current control circuit.

8. The pipeline analog-to-digital converter of claim 5 and wherein a first current is applied to the operational amplifiers during a first phase where the operational amplifiers are amplifying the voltage difference and wherein a second current of smaller magnitude is applied to the operational amplifiers during a second phase where the output of the operational amplifiers is reset to a predetermined value.

9. A method of converting an analog voltage input to a digital signal in a pipeline analog-to-digital converter having a plurality of sequentially connected converter stages, comprising the steps of:
sampling and holding an analog voltage input at each stage;
converting the analog voltage input into an intermediate digital representation in each stage;
converting the digital representation into an intermediate voltage signal in each stage;
amplifying a voltage difference between the output of the sample-and-hold circuit and the intermediate voltage output using an operational amplifier while biased with a first current and setting the output of the operational amplifier to a known value while biased with a second current less than said first current to conserve power.
